(19) United States
(12) Patent Application Publication
(10) Pub. No.: US 2024/0313728 A1
(43) Pub. Date: Sep. 19, 2024

(54) AMPLIFIERS

(71) Applicant: Nordic Semiconductor ASA, Trondheim (NO)

(72) Inventors: Marko PESSA, Oulu (FI); Tuomas LEINONEN, Oulu (FI)

(73) Assignee: Nordic Semiconductor ASA, Trondheim (NO)

(21) Appl. No.: 18/601,651

(22) Filed: Mar. 11, 2024

(30) Foreign Application Priority Data
Mar. 14, 2023 (GB) 2303744.3

(51) Int. Cl. H03G 3/00; H03F 3/24; H03G 1/04

(52) U.S. Cl. CPC H03G 3/001; H03F 3/245; H03F 2200/465; H03G 1/04

(57) ABSTRACT

An amplifier apparatus is arranged to amplify an input signal with a gain based on a digital gain control signal. The amplifier apparatus comprises a digital-to-analogue converter arranged to convert the digital gain control signal into an analogue gain control signal according to a first non-linear relationship between digital gain control signal and analogue gain control signal; and an amplifier circuit portion arranged to amplify the input signal with a gain based on the analogue gain control signal according to a second non-linear relationship between analogue gain control signal and gain. The first non-linear relationship is based on the second non-linear relationship.

### CROSS REFERENCE TO RELATED APPLICATION

This application claims priority from Great Britain Application No. 2303744.3, filed Mar. 14, 2023, which application is incorporated herein by reference in its entirety.

### BACKGROUND OF THE INVENTION

The present invention relates to amplifier apparatuses and methods for amplifying signals.

The amplification of electrical signals has many different useful applications. For instance, radio transmitters typically operate by modulating a carrier signal to encode some data, and then amplifying and broadcasting the signal as radio waves using one or more antennas. The radio signal can then be detected and demodulated by a radio receiver to recover the encoded data.

The distance at which a receiver can successfully recover the encoded data depends somewhat on the power with which the signal is transmitted by the transmitter. In general, high transmitter power outputs enable longer range communications. The transmission power in turn depends in part on a gain provided by a power amplifier in the transmitter.

It is often desirable to control accurately the transmission power of a radio transmitter. For instance, in many countries transmitter power outputs are tightly regulated, with strict power limits in certain frequency bands. Accurate control allows transmission power to be set as close as possible to the regulatory maximums. It may also be beneficial to accurately control the power used by a transmitter device with limited energy resources, e.g. to minimise power variation and maximise battery life. It is also generally desirable to control accurately the gain of an amplifier in other contexts.

In some implementations, a digital gain control signal can be used to control the gain provided by an amplifier. In such cases, the precision with which the gain can be controlled depends on the resolution of the digital gain control signal. For instance, an 8-bit digital gain control signal may be used to select one of 256 different possible gain levels. Many digitally-controlled amplifiers use a digital-to-analogue converter (DAC) to convert the digital gain control signal into an analogue gain control signal that actually controls the gain provided by the amplifier. High precision gain control requires a high-resolution DAC, increasing the complexity and/or size of the front-end portion. Moreover, many amplifiers have a non-linear response to the analogue gain control signal, which can make it difficult to optimise gain control logic.

An improved approach may be desired.

### SUMMARY OF THE INVENTION

According to a first aspect of the present invention there is provided an amplifier apparatus arranged to amplify an input signal with a gain based on a digital gain control signal, the amplifier apparatus comprising:
a digital-to-analogue converter arranged to convert the digital gain control signal into an analogue gain control signal according to a first non-linear relationship between digital gain control signal and analogue gain control signal; and
an amplifier circuit portion arranged to amplify the input signal with a gain based on the analogue gain control signal according to a second non-linear relationship between analogue gain control signal and gain; wherein the first non-linear relationship is based on the second non-linear relationship.

According to a second aspect of the present invention there is provided a method of amplifying an input signal with a gain based on a digital gain control signal, the method comprising:
converting the digital gain control signal into an analogue gain control signal according to a first non-linear relationship between digital gain control signal and analogue gain control signal; and
amplifying the input signal with a gain based on the analogue gain control signal according to a second non-linear relationship between analogue gain control signal and gain;
   wherein the first non-linear relationship is based on the second non-linear relationship.

Thus, it will be appreciated by those skilled in the art that, by using a digital-to-analogue converter (DAC) with a first non-linear response that is based on the second non-linear response of the amplifier, the resulting relationship between the digital gain control signal and the gain provided by the amplifier circuit portion may more easily be optimised for particular implementations. Conventionally, DACs are designed to have a relationship between digital input and analogue output that is as linear as possible, (e.g. to generate an analogue output that is proportional to a value indicated by the digital input). However, if a conventional linear DAC were used in the amplifier apparatus of the present invention, the relationship between the digital gain control signal and the gain would be dictated primarily by the non-linearity of the amplifier circuit portion (i.e. the second non-linear relationship), reducing flexibility.

Using a non-linear DAC to control a non-linear amplifier may allow the DAC's sampling resolution (i.e. the number of different analogue output levels it can produce) to be used more efficiently, allowing a lower resolution DAC to be used whilst maintaining gain control precision.

A non-linear relationship may be understood to mean a relationship whose simplest polynomial approximation over the relevant range of interest (i.e. an operational range of the DAC or amplifier) has one or more non-linear terms (e.g. quadratic or cubic terms) with non-negligible coefficients. When considered empirically, a non-linear relationship may be understood to mean a relationship whose gradient varies by more than 10%, more than 20%, more than 50%, more than 100%, more than 200% or more than 300% across a range of interest.

Conversely, a linear relationship or substantially linear relationship may be understood as a relationship which can be accurately approximated with a linear function over the relevant range of interest (i.e. an operational range of the DAC or amplifier), i.e. a relationship whose simplest polynomial approximation has no or only negligible non-linear terms. Additionally or alternatively, a linear relationship may be understood to mean a relationship whose gradient varies by less than 300%, less than 200%, less than 100%, less than 50%, less than 20% or less than 10% across a range of interest.

The step size of a DAC is the change in level of its analogue output resulting from a single step in the digital input (i.e. an increment or decrement by one). A linear DAC has a constant step size across its entire range of operation (i.e. an increment or decrement in a value indicated by a digital input signal produces the same size step in analogue output signal across the whole range of the DAC). When used with a non-linear amplifier, this fixed step size may correspond to small changes in gain in gently sloping regions of the amplifier gain control signal response but to large changes in gain where the response is steep. To be able to guarantee a desired gain control precision over an entire operational range, a conventional linear DAC must therefore be sized to provide small enough steps in analogue output signal to deliver this precision at even the steepest regions of the non-linear relationship. However, the inventors have recognised that doing so may mean providing unnecessarily precise control in the more-gently sloping regions.

In a set of embodiments, the first non-linear relationship at least partially counteracts non-linearity in the second non-linear relationship. In other words, the first non-linear relationship may be selected to reduce or remove non-linearity in an overall relationship between the digital gain control signal and the gain delivered by the amplifier circuit portion (i.e. compared to the use of a linear DAC). Reducing the non-linearity of this overall relationship may be understood to mean reducing the magnitude of one or more coefficients of non-linear terms in a simplest polynomial approximation of the overall relationship between digital gain control signal and the gain. When viewed another way, reducing non-linearity in the overall relationship may be understood to mean reducing a variation in gradient of the overall relationship between the digital gain control signal and the gain (e.g. reducing a difference between the maximum and minimum gradients of the overall relationship). In some embodiments, there is a substantially linear relationship between the digital gain control signal and the gain delivered by the amplifier circuit portion (i.e. due to appropriate design of the first non-linear relationship).

In such embodiments, because the first non-linear relationship at least partially counteracts non-linearity in the second non-linear relationship, changes in the digital gain control signal may produce more consistently-sized changes in the gain of the amplifier circuit portion across its operational range. As such, the resolution of the DAC (i.e. the number of different analogue gain control signal levels the DAC can produce, or correspondingly a bit-depth of digital gain control signal supported by the DAC) may be distributed more evenly across a range of gains supported by the amplifier circuit portion. This may allow a desired gain control precision to be achieved with a lower-resolution DAC, reducing the size and/or cost of the apparatus compared to conventional approaches to amplification.

As explained above, a linear DAC has a constant step size. In contrast, the non-linear DAC of the present invention has a non-constant step size (i.e. where the change in level of the analogue gain control signal for adjacent values of the digital gain control signal varies over the operational range of the DAC).

The step size of the DAC may vary continuously, such that every possible step in the level of the analogue gain control signal is different across the operational range of the DAC. However, this level of refinement in the first non-linear relationship may not be necessary to provide useful flexibility in many implementations. The DAC may thus instead feature discrete changes in step size across its operational range.

In a set of embodiments, the DAC has a first step size for a first range of the digital gain control signal, and a second step size for a second range of the digital gain control signal (or equivalently for first and second ranges of the analogue gain control signal). The first and second ranges may together span an entire operational range of the DAC, because a DAC with as few as two different step sizes may still be sufficient for useful optimisations of many amplifier apparatuses. For instance, if the second non-linear relationship has distinct gently sloping and steep regions, useful compensation can be achieved by the first step size being large and the first range covering the gently sloping region, and the second step size being small and the second range covering the steep region.

However, it may be useful for the DAC to have a larger number of ranges with different step sizes, i.e. to increase the fidelity with which the first non-linear relationship is defined. In a set of embodiments, the DAC comprises one or more further step sizes for one or more further ranges of the digital gain control signal. In some embodiments, the DAC comprises at least five different step sizes or at least ten different step sizes. The ranges of the digital gain control signal with different step sizes may be equally sized. However, in some embodiments the ranges may have different sizes, e.g. with more changes in step size in regions where the second non-linear relationship is more non-linear.

An appropriate first non-linear relationship may be realised with many different DAC architectures and implementations. However, in a set of embodiments the DAC comprises a current generator portion and a resistor ladder (i.e. a plurality of resistors connected in series). The current generator portion may be arranged to apply one or more currents based on the digital gain control signal to one or more input nodes between resistors of the resistor ladder to generate an analogue voltage at an output node of the resistor ladder (e.g. at an end of the resistor ladder). The analogue voltage at the output node of the resistor ladder may then be used to generate the analogue gain control signal.

The analogue voltage at the output node depends on the magnitude of current flowing through the resistor ladder (i.e. according to Ohm's law). Thus, by controlling appropriately the magnitude(s) and input position(s) of current(s) applied to the resistor ladder, a desired non-linear relationship between the digital gain control signal and the analogue gain control signal can be realised.

In some embodiments the current generator portion is arranged to:
apply a first current to a first input node of the resistor ladder, the magnitude of the first current varying monotonically with the digital gain control signal between a minimum when the digital gain control signal indicates a first value and a maximum when the digital gain control signal indicates a second, higher value or higher; and
if the digital gain control signal indicates a value higher than the second value, additionally apply a second current to a second node in the resistor ladder, the magnitude of the second current varying monotonically with the digital gain control signal between a minimum when the digital gain control signal value indicates the second value and a maximum when the digital gain control signal indicates a third, higher value or higher.

It will be recognised that in such embodiments, the first and second values define a first range and the monotonic relationship between the magnitude of the first current and the digital gain control signal along with the position of the first input node determines a step size of the DAC in that first range. Correspondingly, the second and third values define a second range and the monotonic relationship between the magnitude of the second current and the digital gain control signal along with the position of the second input node determines a step size of the DAC in the second range.

In some embodiments, the first and second currents have the same minimum (e.g. 0 A). In some embodiments the first and/or second currents are proportional to the digital gain control signal (i.e. there is a constant current step size across the first and/or second range). In some such embodiments the first and second currents have the same constant of proportionality, so that the current step size is the same for the first and second range. It will be appreciated that in such embodiments the non-linearity of the first non-linear relationship arises due to the different input nodes to which the first and second currents are applied. A desired first non-linear relationship may advantageously then be achieved simply by appropriate selection of the resistances of the resistors in the resistor ladder.

Whilst two ranges with different step size behaviour may be sufficient for some situations, in some embodiments the current generator portion is operable to apply one or more further currents to one or more further input nodes when the digital gain control signal indicates a value in one or more further ranges.

The analogue voltage at the output node of the resistor ladder may simply be provided as the analogue gain control signal. However, in some embodiments the DAC comprises one or more further components or stages arranged to generate the analogue gain control signal using on the analogue voltage. For instance, in a set of embodiments, the DAC comprises a buffer stage arranged to amplify the analogue voltage to produce the analogue gain control signal. Amplifying the analogue voltage with a buffer stage may mean that earlier components in the DAC only need to handle smaller voltages/currents and can thus be made smaller and less expensive. Moreover, an amplitude range of the analogue gain control signal may be modified (e.g. for different implementations) by changing only the buffer stage and keeping earlier components the same, simplifying manufacture.

Furthermore, using a buffer stage may allow the DAC to be better matched to the amplifier circuit portion (e.g. to compensate more consistently for the second non-linear relationship). For instance, the buffer stage may comprise one or more transistors, such as one or more source follower transistors in a closed op-amp feedback loop. One or more properties of said one or more transistors may be matched to one or more corresponding transistors of the amplifier circuit portion. Matching one or more transistors with the amplifier may mitigate relative variations in DAC and amplifier behaviour due to process variations and variations in operating conditions (e.g. changes in temperature or supply voltage), improving the consistency of optimisations achieved by basing the first non-linear relationship on the second non-linear relationship.

Optimising amplifier control may be useful in many amplifier implementations. The input signal may be any electrical signal that requires amplification. However, the present invention may be particularly suited to radio transmission implementations. In a set of embodiments, the input signal is a radio frequency signal (e.g. having a frequency between 20 KHz and 300 GHz or between 100 MHz and 30 GHZ). The input signal may be a microwave frequency signal (e.g. having a frequency of over 1 GHZ). The input signal may have a frequency of approximately 2.4 GHz. For instance, the input signal may be compatible with a Bluetooth communication standard.

The amplifier circuit portion may comprise a dedicated amplifier device, e.g. provided as a separate device to the DAC. However, in a set of embodiments, the amplifier apparatus comprises a single device comprising the DAC and the amplifier circuit portion.

According to a third aspect of the present invention there is provided a device comprising a control circuit portion and an amplifier apparatus as described herein. The control circuit portion may comprise a microprocessor. In a set of embodiments the control circuit portion comprises a System-on-Chip (SoC). The DAC may be provided together with the control circuit portion (e.g. as part of the same microprocessor or SoC).

The control circuit portion may be arranged to generate the digital gain control signal (that controls the gain provided by the amplifier apparatus).

The device may be a radio transmitter device that is arranged to transmit an amplified version of the input signal as a radio signal after amplification by the amplifier apparatus.

The radio transmitter device may be arranged to sense a transmission power of the transmitted radio signal. For instance, the radio transmitter device may comprise a sensor arranged to sense a power of the amplified version of the input signal. The sensor may be arranged to sample the amplified version of the input signal and convert this sample into a DC voltage proportional to the power of the amplified signal. The sensor may be arranged to produce a transmission power feedback signal indicating a power of the transmitted radio signal. The transmission power feedback signal may comprise the DC voltage proportional to the power of the amplified signal.

The transmission power depends in part on the gain provided by the amplifier apparatus. The control circuit portion may be arranged to generate the digital gain control signal based on a sensed transmission power (e.g. based on the transmission power feedback signal). In some embodiments, the control circuit portion is arranged to control the digital gain control signal so as to maintain a transmission power at, above or below a desired power level (e.g. below a regulatory transmission power limit). For example, if the control circuit portion senses that the transmission power is increasing, it may reduce the value of a digital gain control signal to reduce a gain provided by the amplifier apparatus and thus counteract the sensed increase in the transmission power.

Reducing non-linearity in the overall relationship between the digital gain control signal and the amplifier gain may be particularly useful in embodiments where the digital gain control signal is controlled based on transmission power feedback, because there may be less variation in how much the digital gain control signal needs to change to compensate for a sensed offset in transmission power across the operational range of the amplifier apparatus. This may enable the use of simpler and/or faster feedback control logic. For instance, in embodiments where there is a substantially linear relationship between the digital gain control signal and the transmission gain, feedback control logic may not need to take into account at all the absolute value of the digital gain control signal when determining the appropriate response.

Moreover, because the resolution of the non-linear DAC can be more efficiently distributed over an operational range of gains, a feedback control loop may be made faster by avoiding regions where single increments or decrements in the digital gain control signal (that may be performed by feedback control logic) cause only very small changes in output gain.

The control circuit portion may be arranged to provide the input signal to the amplifier apparatus. Alternatively, a separate circuit portion or an entirely separate device may provide the input signal (e.g. the device may be a radio transmitter front-end device arranged to handle amplification and transmission of the input signal).

Features of any aspect or embodiment described herein may, wherever appropriate, be applied to any other aspect or embodiment described herein. Where reference is made to different embodiments, it should be understood that these are not necessarily distinct but may overlap.

### BRIEF DESCRIPTION OF THE DRAWINGS

One or more non-limiting examples will now be described, by way of example only, and with reference to the accompanying figures in which:

FIG. 1 is a schematic diagram of a transmitter device according to an embodiment of the invention;

FIG. 2 is a graph illustrating a relationship between analogue gain control signal and transmission power;

FIG. 3 is a graph illustrating a step size of a DAC of the transmitter device;

FIG. 4 is a graph illustrating a relationship between digital gain control signal and transmission power;

FIG. 5 is a schematic diagram of a DAC used in embodiments of the invention;

FIG. 6 is a schematic diagram of the splitter portion of the DAC;

FIG. 7 is a schematic diagram of the coding portion of the DAC;

FIG. 8 is a schematic diagram of the current generator portion of the DAC; and

FIG. 9 is a schematic diagram of the resistor ladder and the buffer portion of the DAC.

### DETAILED DESCRIPTION

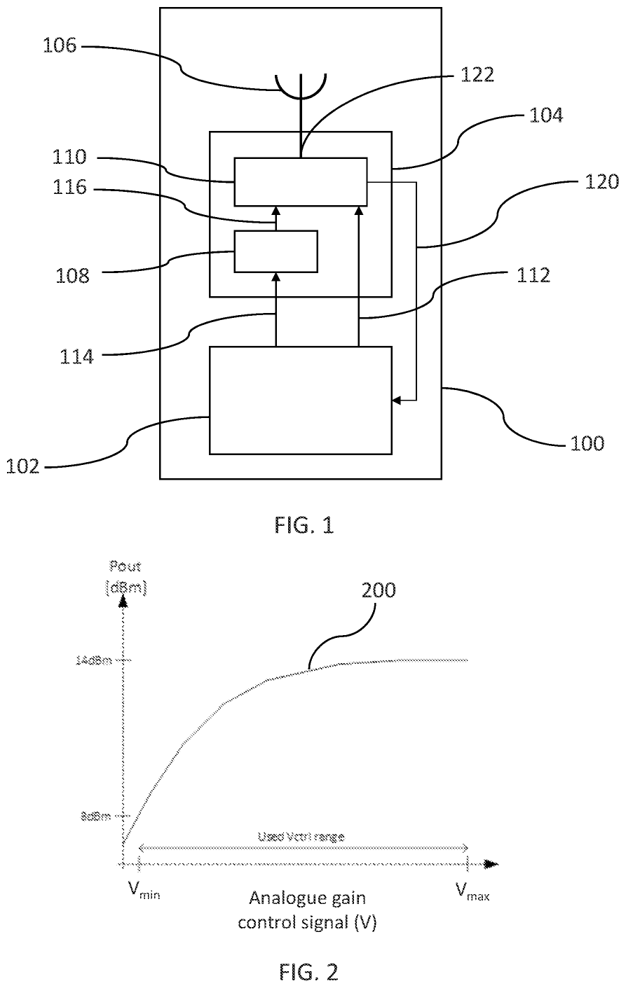

FIG. 1 shows a transmitter device 100 comprising a System on Chip (SoC) 102, an RF front-end portion 104 and an antenna 106. The front-end portion 104 comprises a digital-to-analogue converter (DAC) 108 and a power amplifier 110.

In use, the SoC 102 generates radio frequency electrical signals 112 (e.g. in which data to be transmitted is encoded) and sends these to the front-end portion 104 along with a digital gain control signal 114. The SoC 102 uses the digital gain control signal 114 to control precisely a gain that the power amplifier 110 applies when amplifying the signals 112. Alternatively, logic in the front-end portion 104 itself may control the digital gain control signal 114 to control the gain. An output 122 of the power amplifier 110 outputs an amplified version of the electrical signals 112 to the antenna 106 for transmission.

The SoC 102 receives a transmission power feedback signal 120 from the power amplifier 110. The transmission power feedback signal 120 indicates a transmission power with which the signals 112 are being transmitted. The transmission power with which the signals 112 are transmitted may vary during use, e.g. due to changing environmental conditions such as temperature. The SoC 102 continually adjusts the digital gain control signal 114 based on the feedback signal 120 to keep the transmission power of the transmitter device 110 below, but as close as possible to, a regulatory transmission power limit. For instance, if the transmission power feedback signal 120 indicates that the output transmission power is increasing from a target level, the SoC 112 reduces the digital gain control signal 114 by one or more steps to counteract this.

The DAC 108 receives the digital gain control signal 114 and produces an analogue gain control signal 116 based on the value indicated by the digital gain control signal 114. The analogue gain control signal 116 is a voltage ranging between a minimum gain control voltage Vₘᵢₙ and a maximum gain control voltage Vₘₐₓ.

The analogue gain control signal 116 is input to the power amplifier 110 and controls the transmission gain applied to the radio signals 112 by the power amplifier 110. When the analogue gain control signal 116 has the minimum gain control voltage Vₘᵢₙ, the power amplifier 110 applies a minimum transmission gain, and when the analogue gain control signal 116 has the maximum gain control voltage Vₘₐₓ, the power amplifier 110 applies a maximum transmission gain. The precision with which the gain can be adjusted is determined by the precision with which the DAC 108 can adjust the analogue gain control signal 116 (i.e. the resolution of the DAC 108).

The power amplifier 110 has a non-linear relationship between voltage of the analogue gain control signal 116 and gain delivered by the power amplifier 110. The gain of the power amplifier 110 determines the transmission power of the transmitter device, so the resulting relationship between voltage of the analogue gain control signal 116 and transmission power is also non-linear. This non-linear relationship 200 between the voltage of the analogue gain control signal 116 input to the power amplifier 110 and the transmission power of the radio signals 112 is illustrated in FIG. 2. The plot in FIG. 2 uses logarithmic units for transmission power (dBm) on the y-axis, but the relationship is non-linear even when measured standard linear power units (W) are used.

The non-linear relationship illustrated in FIG. 2 means that at lower voltages, a given change in the analogue gain control signal 116 leads to a much larger change in output gain that at higher voltage. To maintain a given level of gain control precision over the whole range, the DAC 108 must be able to deliver very small changes in the analogue gain control signal 116 in the lower range. One solution could be to use a very high resolution linear DAC 108. However, this results in a lot of “wasted” resolution at the higher voltages where small changes in the analogue gain control signal 116 are not needed. The large changes in the digital gain control signal 114 needed to effect changes in the gain at the higher voltages can also slow down control.

Therefore, the DAC 108 is designed to have a non-linear relationship between digital gain control signal 114 and analogue gain control signal 116 that counteracts the non-linear relationship of the power amplifier 110 to produce an overall relationship between the digital gain control signal 114 and the output gain (and thus the transmission power) that is substantially linear.

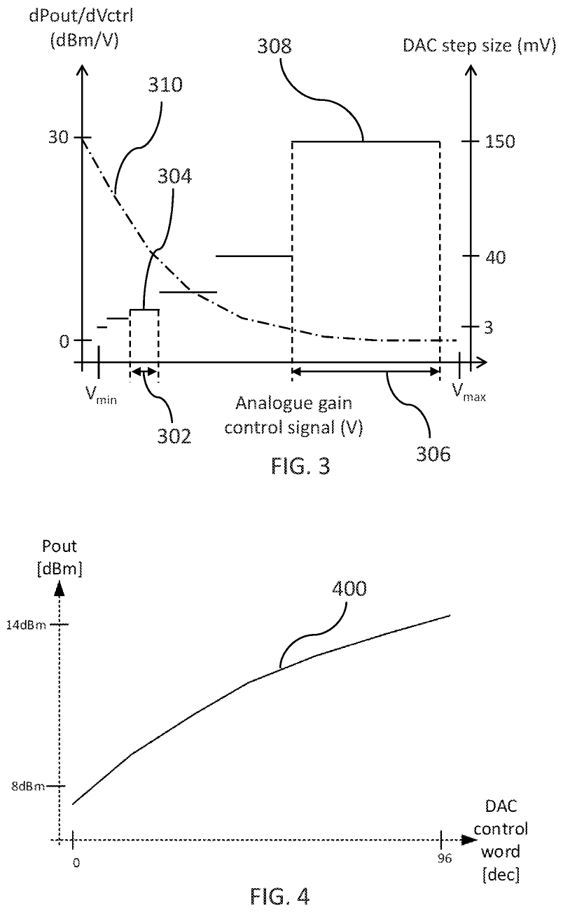

The non-linear relationship of the DAC 108 is illustrated in FIG. 3. The non linear relationship is realised by the DAC 108 having six different step sizes for six different ranges of the digital gain control signal (and equivalent ranges of the analogue gain control signal). For instance in a first range 302 at a low signal level, the step size 304 of the DAC (i.e. the change in analogue gain control signal for an increment in the digital gain control signal) is small. In a second higher range 306, the step size 308 is much larger.

FIG. 3 also illustrates the derivative 310 of the non-linear relationship between analogue gain control signal 116 and transmission power (i.e. the relationship illustrated in FIG. 2), showing how the variable step size of the DAC compensates for the changing gradient of the amplifier response.

The result of combining the first non-linear relationship of the DAC 108 with the second non-linear relationship of the power amplifier 110 is that the overall relationship between the digital gain control signal 114 and the output gain (and thus the transmission power) is substantially linear. This linear overall relationship 400 is illustrated in FIG. 4.

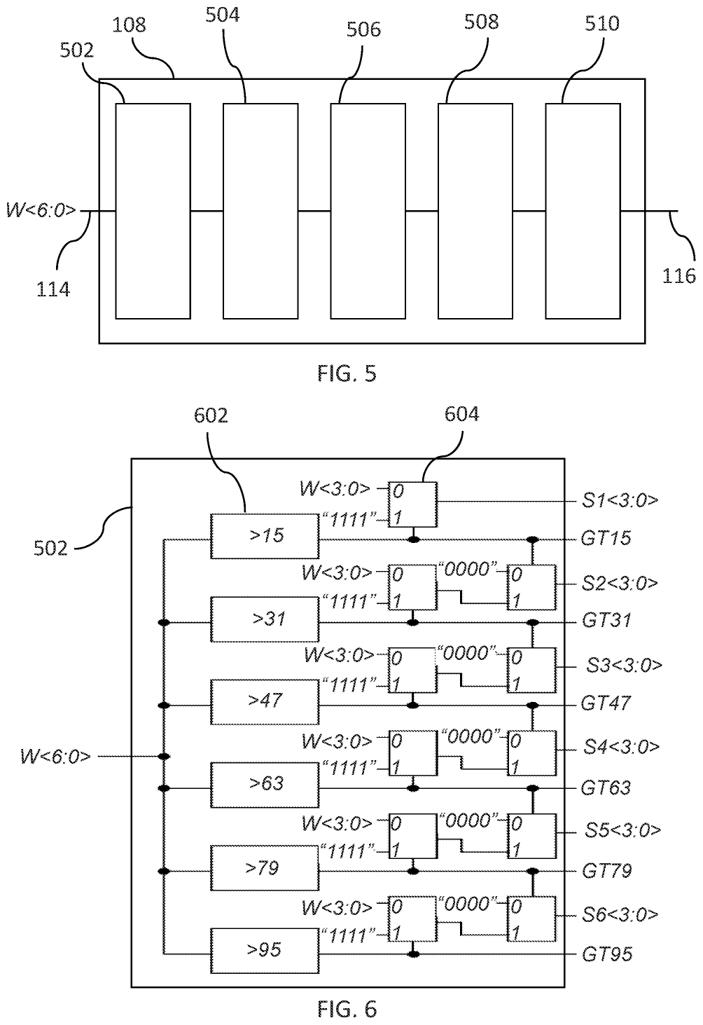

The structure and operation of the DAC 108 will now be described in more detail with additional reference to FIG. 5 to FIG. 9.

The DAC 108 comprises a splitter portion 502, a coding portion 504, a current generator portion 506, a resistor ladder 508 and an output buffer portion 510.

The DAC 108 receives the digital gain control signal 114. In this example the digital gain control signal 114 is a 7-bit control word W<6:0> (i.e. indicating a value between 0 and 127). The splitter portion 502 is shown in more detail in FIG. 6. The splitter portion 502 comprises an arrangement of comparison portions 602 and multiplexers 604 which splits the 7-bit control word into six 4-bit signals S1<3:0>-S6<3:0> corresponding to six ranges of 16 values of the digital gain control signal 114, along with a set of overflow bits GT15-GT95.

For example, if digital gain control signal 114 indicates a value of 18, signal GT15 is set to 1, signal S1<3:0> is set to “1111”, signal S2<3:0> is set to “0010” and the remaining signals are all at 0 (because the value is greater than the range corresponding to the first signal S1<3:0>, and is two higher than the lower bound of the range corresponding to the second signal S2<3:0>.

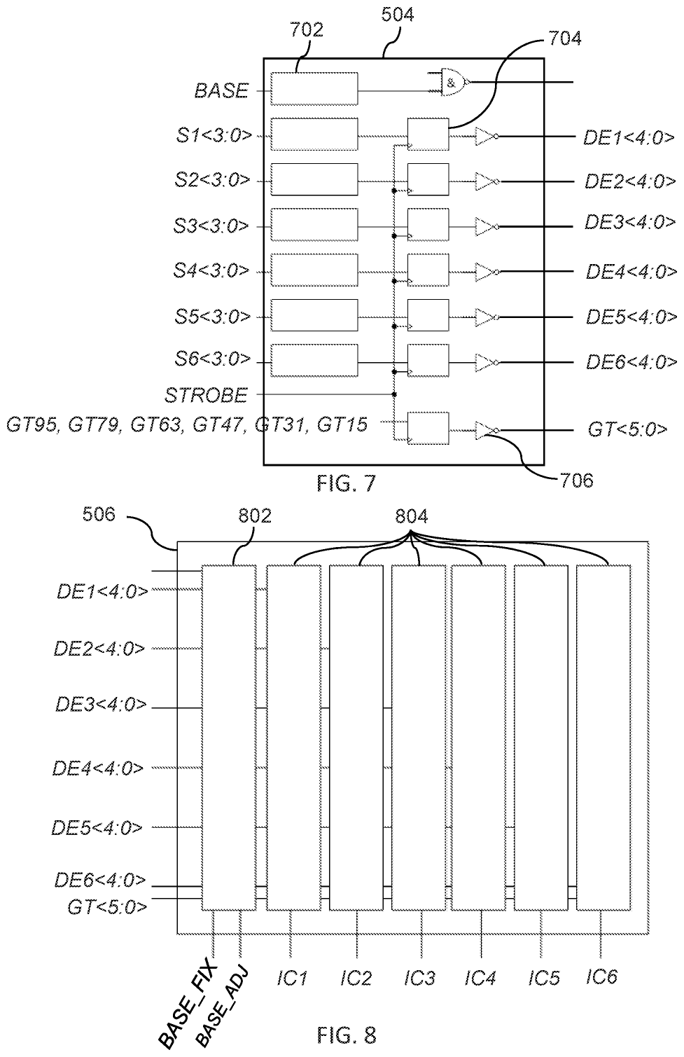

The signals from the splitter portion 502 are directed to the coding portion 504, shown in more detail in FIG. 7. The coding portion 504 comprises a plurality of unary coders 702, flip flops 704 and inverters 706 which convert the 4-bit Sx<3:0> signals and the overflow bits into six 5-bit signals DEx<4:0> and a 6-bit overflow signal GT<5:0>. The coding portion 504 is clocked by a STROBE signal. The coding portion also receives a BASE signal used to set or trim the lower limit of the analogue gain control signal, i.e. Vₘᵢₙ.

The signals DEx<4:0>, GT<5:0> are sent to the current generator portion 506. The current generator portion 506 is shown in more detail in FIG. 8 and comprises a plurality of current-output DAC slices 802, 804. A first slice 802 receives a signal derived from the BASE signal and outputs BASE_FIX and BASE_ADJ signals. BASE_FIX is a fixed part and BASE_ADJ is trims the lower limit of the analogue gain control signal Vₘᵢₙ to a desired level (e.g. to correct for production variations).

The remaining six slices 804 correspond to the six ranges of 16 values of the digital gain control signal 114 used by the splitter portion 502. The slices 804 operate to output a current ICX as follows:
if the value of the digital gain control signal 114 is less than the lower bound of the relevant range, output no current;
if the value of the digital gain control signal 114 is greater than the upper bound of the relevant range, output a maximum current; and
If the value of the digital gain control signal 114 is in the relevant range, output a current that is proportional to the difference between the value of the digital gain control signal 114 and the lower bound of the relevant range.

As a result, all of the slices 804 corresponding to ranges less than the value of the digital gain control signal 114 output a maximum current, all of the slices 804 corresponding to ranges greater than the value of the digital gain control signal 114 output zero current, and the slice 804 corresponding to the range containing the value of the digital gain control signal 114 outputs a current proportional to the position of that value within the relevant range. All of the slices are configured identically, so that a given change in the digital gain control signal 114 in any of the ranges results in the same change in output current of the relevant slice 804 (i.e. the step size in total current output by the current generator portion 506 is constant). The non-linearity of the DAC is instead provided by the resistor ladder 508.

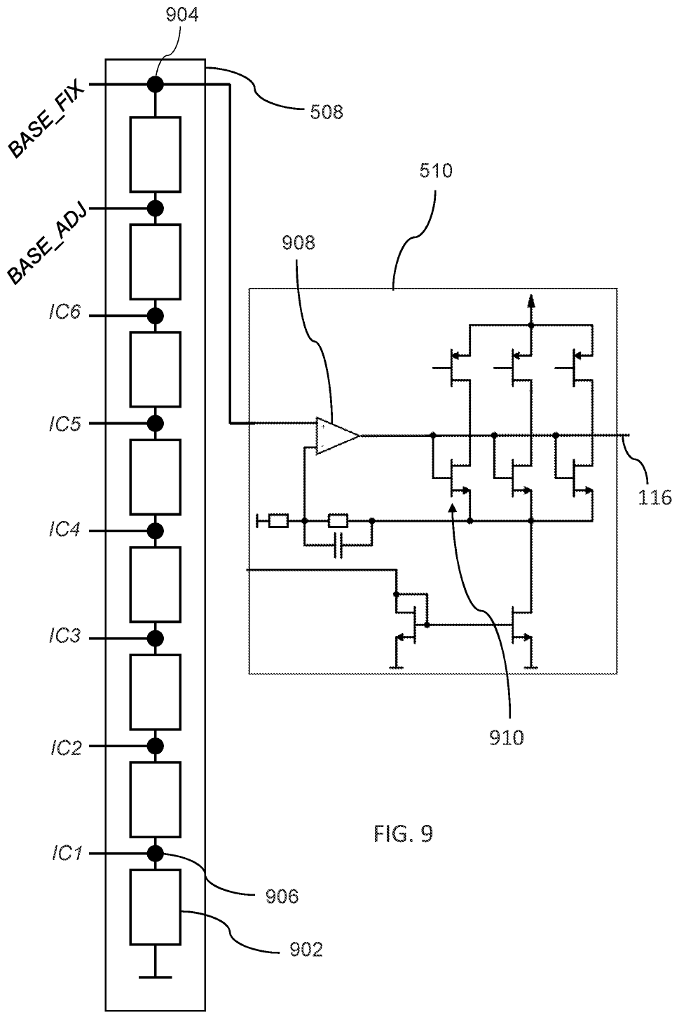

The resistor ladder 508 is shown in more detail in FIG. 9. The resistor ladder comprises a plurality of resistors 902 connected in series between ground and an output node 904. There is an input node 906 between each pair of resistors 902. Each of the currents ICX output by the current generator portion 506 is sent to a different input node of the resistor ladder 508.

The voltage at the output node 904 of the resistor ladder depends on the magnitude of each of the currents ICX and the resistances of the resistors 902. As explained above, the step size of total current output by the current generator portion 506 is constant. However, the constant steps in current are input to different input nodes 906. As such, the step size in the output voltage at the output node varies depending on which DAC slice 804 is providing the changing current. The output voltage step size thus varies depending on the absolute value of the digital gain control signal 114 (i.e. depending on which of the six ranges it falls into). This results in the six different DAC step sizes shown in FIG. 3 (and the non-linear behaviour of the DAC 108). The profile of this non-linearity may be tuned (e.g. for a particular amplifier 110) by selecting appropriate resistances for each of the resistors 902 in the resistor ladder 508.

Finally, the output voltage from the resistor ladder 508 is input to the output buffer portion 510, also illustrated in FIG. 9. The buffer portion 510 comprises an operational amplifier 908 with a feedback loop comprising three source follower transistors 910. The source follower transistors 910 are matched to corresponding transistors in the power amplifier, to minimise the impact of process and operational variations on the operation of the radio transmitter device 100. The buffer portion 510 outputs an amplified version of the output voltage as the analogue gain control signal 116.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

1. An amplifier apparatus arranged to amplify an input signal with a gain based on a digital gain control signal, the amplifier apparatus comprising:
a digital-to-analogue converter arranged to convert the digital gain control signal into an analogue gain control signal according to a first non-linear relationship between digital gain control signal and analogue gain control signal; and
an amplifier circuit portion arranged to amplify the input signal with a gain based on the analogue gain control signal according to a second non-linear relationship between analogue gain control signal and gain;
wherein the first non-linear relationship is based on the second non-linear relationship.

2. The amplifier apparatus of claim 1, wherein the first non-linear relationship at least partially counteracts non-linearity in the second non-linear relationship.

3. The amplifier apparatus of claim 1, wherein the digital-to-analogue converter has a first step size for a first range of the digital gain control signal, and a second step size for a second range of the digital gain control signal.

4. The amplifier apparatus of claim 3, wherein the digital-to-analogue converter comprises one or more further step sizes for one or more further ranges of the digital gain control signal.

5. The amplifier apparatus of claim 4, wherein the digital-to-analogue converter comprises at least five different step sizes.

6. The amplifier apparatus of claim 1, wherein the digital-to-analogue converter comprises a current generator portion and a resistor ladder, wherein the current generator portion is arranged to apply one or more currents based on the digital gain control signal to one or more input nodes between resistors of the resistor ladder to generate an analogue voltage at an output node of the resistor ladder.

7. The amplifier apparatus of claim 6, wherein the current generator portion is arranged to:
apply a first current to a first input node of the resistor ladder, the magnitude of the first current varying monotonically with the digital gain control signal between a minimum when the digital gain control signal indicates a first value and a maximum when the digital gain control signal indicates a second, higher value or higher; and
if the digital gain control signal indicates a value higher than the second value, additionally apply a second current to a second node in the resistor ladder, the magnitude of the second current varying monotonically with the digital gain control signal between a minimum when the digital gain control signal value indicates the second value and a maximum when the digital gain control signal indicates a third, higher value or higher.

8. The amplifier apparatus of claim 7, wherein the first and/or second currents are proportional to the digital gain control signal.

9. The amplifier apparatus of claim 6, wherein the digital-to-analogue converter comprises a buffer stage arranged to amplify the analogue voltage to produce the analogue gain control signal.

10. The amplifier apparatus of claim 9, wherein the buffer stage comprises one or more transistors with one or more properties matched to one or more corresponding transistors of the amplifier circuit portion.

11. The amplifier apparatus of claim 10, wherein the one or more transistors comprise one or more source follower transistors in a closed op-amp feedback loop.

12. A device comprising a control circuit portion and the amplifier apparatus of claim 1, wherein the control circuit portion is arranged to generate the digital gain control signal.

13. The device of claim 12, wherein the device is a radio transmitter device that is arranged to transmit an amplified version of the input signal as a radio signal after amplification by the amplifier apparatus.

14. The device of claim 13, arranged to sense a transmission power of the transmitted radio signal wherein the control circuit portion is arranged to generate the digital gain control signal based on a sensed transmission power.

15. The device of claim 14, wherein the control circuit portion is arranged to control the digital gain control signal so as to maintain a transmission power at or above a desired power level.

16. The device of claim 14, wherein the control circuit portion is arranged to control the digital gain control signal so as to maintain a transmission power at or below a desired power level.

17. The device of any claim 12, wherein the control circuit portion is arranged to provide the input signal to the amplifier apparatus.

18. A method of amplifying an input signal with a gain based on a digital gain control signal, the method comprising:
converting the digital gain control signal into an analogue gain control signal according to a first non-linear relationship between digital gain control signal and analogue gain control signal; and
amplifying the input signal with a gain based on the analogue gain control signal according to a second non-linear relationship between analogue gain control signal and gain;
wherein the first non-linear relationship is based on the second non-linear relationship.
